(19) United States
(12) Patent Application Publication
(10) Pub. No.: US 2013/0095585 A1
(43) Pub. Date: Apr. 18, 2013

(54) MULTI-FIELD ARRANGING METHOD OF LED CHIPS UNDER SINGLE LENS

(71) Applicant: Helio Optoelectronics Corporation, Zhudong Town (TW)

(72) Inventors: Ming-Hung CHEN, Zhudong Town (TW); Po-Ming Tseng, Zhudong Town (TW); Kun-Yang Hsieh, Zhudong Town (TW); Shin-Chieh Lin, Zhudong Town (TW)

(73) Assignee: Helio Optoelectronics Corporation, Zhudong Town (TW)

(21) Appl. No.: 13/708,720

(22) Filed: Dec. 7, 2012

Related U.S. Application Data
(63) Continuation-in-part of application No. 13/057,183, filed on Feb. 2, 2011, now abandoned.

(51) Int. Cl. H01L 33/00

(52) U.S. Cl. CPC H01L 33/005
USPC 438/29

(57) ABSTRACT

A multi-field arranging method of LED chips under a single lens includes the steps of: setting a first concentric circle on a bottom of a hemispherical lens, wherein the first concentric circle is centered at an axis of the hemispherical lens; equidistantly arranging plural first LED chips on the first concentric circle; setting a second concentric circle, which is also centered at the same axis as the first concentric circle, and the second concentric circle is larger than the first concentric circle in radius; and equidistantly arranging plural second LED chips and plural third LED chips on the second concentric circle. The present invention allows the LED chips to present symmetrical light patterns through the hemispherical lens, thereby obtaining a light field with evener color mixture and evener color temperature distribution in every illuminating direction.

### CROSS-REFERENCE TO RELATED APPLICATION

This application is a continuation-in-part (CIP) of U.S. patent application Ser. No. 13/057,183 filed on Feb. 2, 2011, which claims benefit of PCT application number PCT/CN/2008001641 filed on Sep. 23, 2008 and entitled “MULTI-FIELD ARRANGING METHOD OF LED CHIPS UNDER SINGLE LENS”. The disclosure of the related applications is incorporated herein by reference.

### BACKGROUND OF THE INVENTION

1. Technical Field

The present invention relates to LED arranging methods, and more particularly, to a multi-field arranging method of LED chips under a single lens applicable to color mixture of multiple LED chips.

2. Description of Related Art

FIG. 1 is a diagram showing light intensity profiles through a conventional hemispherical lens 10. FIG. 2 is another diagram showing light intensity profiles through the conventional hemispherical lens 10. FIG. 3 is a diagram showing light intensity profiles through a conventional planar lens.

FIG. 1 and FIG. 2 are the two diagrams are derived from measuring the light intensity profiles of LED chips of different colors from two different viewpoints through the conventional hemispherical lens 10. According to the diagrams, it is found that since the hemispherical lens 10 has its axis 11 inconsistent with the optical axis of any of the colored LEDs, the resultant light patterns of all the LEDs are asymmetric and varied with viewpoints.

Referring to FIG. 3, while the planar lens gives symmetrical light patterns, most of the emitted light is reflected by the planar lens, causing the overall light extraction efficiency reduced by half as compared with that through the hemispherical lens 10.

FIG. 4A is a schematic drawing illustrating LED chips of three colors arranged under the conventional hemispherical lens 10. FIG. 4B shows the light pattern of the red LED chip under the conventional hemispherical lens 10. FIG. 4C shows the light pattern of the green LED chip under the conventional hemispherical lens 10. FIG. 4D shows the light pattern of the blue LED chip under the conventional hemispherical lens 10.

Referring to FIG. 4A, subject to the relative locations of the LED chips of different colors in the same space and differences between the axis 11 of the hemispherical lens 10 and the optical axis of each of the LED chips, the light patterns of the red LED chip, the green LED chip, and the blue LED chip under the hemispherical lens 10 are as shown in FIG. 4B, FIG. 4C, and FIG. 4D, respectively, all being asymmetric. Thus, polarized light is generated and causes poor color mixture at the peripheral portion of the hemispherical lens 10.

This proves that the existing technology for arranging LED chips under a hemispherical lens still fails to present light patterns that are flawless and convenient to practical applications and needs to be improved. For remedying these problems, the related manufacturers have long spent every effort to develop solutions, yet a suitable design is still absent. Hence, an efficacious multi-field arranging method of LED chips under single lens is, exactly the target the industry is seeking for.

In view of the defective light patterns of the existing configurations of LED chips under a hemispherical lens, the inventor of the present invention has, with his years of abundant experience, an professionalism in designing and producing LED products, applied relevant theories to actively research and innovate in expectation to create a novel multi-field arranging method of LED chips under single lens that improve light patterns and is more applicable. After repeated researches, designs, tests and modifications, the present invention of practical value is herein presented.

### SUMMARY OF THE INVENTION

One objective of the present invention is to overcome the defects of the light patterns produced by the existing configurations of LED chips under a hemispherical lens, and to provide a new multi-field arranging method of LED chips under a single lens, wherein the technical issue to be addressed is to make each of the LED chips of different vertical divergence angles under the hemispherical lens present a symmetrical light pattern, so as to allow even color mixture, and the color temperature distribution will also be evener in every illuminating direction, and thus being more practical.

Another objective of the present invention is to provide a new multi-field arranging method of LED chips under a single lens, wherein the technical issue to be addressed is to such arrange the LED chips of various vertical divergence angles at a bottom of the single lens that a light pattern formed by mixture of the light of the LED chips is symmetrical from any viewpoint, thereby improving color mixture at the peripheral portion of the single lens, thus being more practical.

Still another objective of the present invention is to provide a new multi-field arranging method of LED chips under a single lens, wherein the technical issue to be addressed is to arrange the LED chips into concentric circles, so as to maximize the density of the LED chips and thereby downsize the overall configuration, thus being more practical.

To achieve the objectives and to address the technical issues of the present invention, the following technical scheme is adopted. According to the present invention, a multi-field arranging method of LED chips under a single lens, the method comprising steps of: setting a first concentric circle on a bottom of a hemispherical lens, wherein the first concentric circle is centered at an axis of the hemispherical lens; arranging at least three first LED chips having a first vertical divergence angle on the first concentric circle, wherein the first LED chips are arranged equidistantly; setting a second concentric circle on the bottom of the hemispherical lens, wherein the second concentric circle is centered at the axis of the hemispherical lens, and the second concentric circle is larger than the first concentric circle in radius; and arranging at least three second LED chips and at least three third LED chips, wherein each said second LED chip has a second vertical divergence angle and each said third LED chip has a third vertical divergence angle; wherein the first vertical divergence angle is smaller than the second vertical divergence angle or the third vertical divergence angle, and the second vertical divergence angle does not equal to the third vertical divergence angle.

To further achieve the objectives and to further address the technical issues of the present invention, the following technical measures may also be implemented.

In the foregoing multi-field arranging method, the first LED chips are arranged into an equilateral triangle.

In the foregoing multi-field arranging method, each of the first LED chips, the second LED chips, and the third LED chips has a bottom, and all of the bottoms are mutually parallel.

In the foregoing multi-field arranging method, one of first imaginary lines, which is links between a center of the second concentric circle and a center of one said second LED chip, has an included angle of 40° with one of second imaginary lines, which links between the center of the second concentric circle and a center of one said third LED chip anticlockwise adjacent to said second LED chip, while one of the first imaginary lines has an included angle of 80° with one of third imaginary lines, which links between the center of the second concentric circle and the center of one said third LED chip clockwise adjacent to said second LED chip.

As compared with prior art, the present invention has obvious benefits and profitable effects. It is learned from the foregoing technical schemes that the major technical contents of the present invention are as follows:

To achieve the aforementioned objectives, the present invention provides a multi-field arranging method of LED chips under a single lens, the method comprising steps of: setting a first concentric circle on a bottom of a hemispherical lens, wherein the first concentric circle is centered at an axis of the hemispherical lens; arranging at least three first LED chips having a first vertical divergence angle on the first concentric circle, wherein the first LED chips are arranged equidistantly; setting a second concentric circle on the bottom of the hemispherical lens, wherein the second concentric circle is centered at the axis of the hemispherical lens, and the second concentric circle is larger than the first concentric circle in radius; and arranging at least three second LED chips and at least three third LED chips, wherein each said second LED chip has a second vertical divergence angle and each said third LED chip has a third vertical divergence angle, respectively; wherein the first vertical divergence angle is smaller than the second vertical divergence angle or the third vertical divergence angle, and the second vertical divergence angle does not equal to the third vertical divergence angle.

As compared with prior art, the present invention has obvious benefits and profitable effects. With the above technical schemes, the multi-field arranging method of the present invention at least has the following benefits and profitable effects:

The multi-field arranging method, when applied to a single lens, allows each of the LED chips of different vertical divergence angles to present a symmetrical light pattern through the single lens.

Since each of the LED chips of different vertical divergence angles is allowed to present the symmetrical light pattern, the resultant color mixture can be evener, and an evener color temperature in any one illuminating direction is obtained.

The multi-field arranging method helps to maximize the density of the LED chips and thereby downsize the overall configuration.

To sum up, the present invention relates to a multi-field arranging method of LED chips under a single lens, the method comprising steps of setting a first concentric circle on a bottom of a hemispherical lens, wherein the first concentric circle is centered at an axis of the hemispherical lens; arranging at least three first LED chips having a first vertical divergence angle on the first concentric circle, wherein the first LED chips are arranged equidistantly; setting a second concentric circle on the bottom of the hemispherical lens, wherein the second concentric circle is centered at the axis of the hemispherical lens, and the second concentric circle is larger than the first concentric circle in radius; and arranging at least three second LED chips and at least three third LED chips, wherein each said second LED chip has a second vertical divergence angle and each said third LED chip has a third vertical divergence angle, respectively; wherein the first vertical divergence angle is smaller than the second vertical divergence angle or the third vertical divergence angle, and the second vertical divergence angle does not equal to the third vertical divergence angle.

The LED chips are equidistantly arranged on the first concentric circle and the second concentric circle, so that all the LED chips are allowed to present a symmetrical light pattern under the hemispherical lens, thereby achieving a light field of an evener color mixture and an evener color temperature in every illuminating direction. The present invention possessing the above-recited advantageous and practical merits has made significant improvement in both process and function, so as to provide obvious progress to the related technology and produce useful and practical effects. The present invention, as compared with the known configurations of LED chips under a hemispherical lens, has enhanced, outstanding effects, thus being more practical and being exactly a novel, progressive and practical approach.

### BRIEF DESCRIPTION OF THE DRAWINGS

The invention as well as a preferred mode of use, further objectives and advantages thereof will be best understood by reference to the following detailed description of illustrative embodiments when read in conjunction with the accompanying drawings, wherein:

FIG. 1 is a diagram showing light intensity profiles through a conventional hemispherical lens;

FIG. 2 is another diagram showing light intensity profiles through the conventional hemispherical lens;

FIG. 3 is a diagram showing light intensity profiles through a conventional planar lens;

FIG. 4A is a schematic drawing illustrating LED chips of three colors arranged under the conventional hemispherical lens;

FIG. 4B shows the light pattern of the red LED chip under the conventional hemispherical lens;

FIG. 4C shows the light pattern of the green LED chip under the conventional hemispherical lens;

FIG. 4D shows the light pattern of the blue LED chip under the conventional hemispherical lens;

FIG. 5 is a flowchart of a multi-field arranging method of LED chips under a single lens according to a preferred embodiment of the present invention;

FIG. 6 is a view of the first and the second concentric circles under the single lens according to FIG. 5;

FIG. 7 is an exemplificative arrangement of the LED chips according to the preferred embodiment;

FIG. 8 is another exemplificative arrangement of the LED chips according to the preferred embodiment;

FIG. 9 is still another exemplificative arrangement of the LED chips according to the preferred embodiment;

FIG. 10 is the graphical presentation of a vertical divergence angle of a LED chip;

FIG. 11 is the graphical presentation of the evener color temperature distribution of the LED chips in one illuminating direction according to the preferred embodiment of the invention; and

FIG. 12 is the graphical presentation of the scanning arrangement for obtaining the color temperature distribution as in FIG. 11.

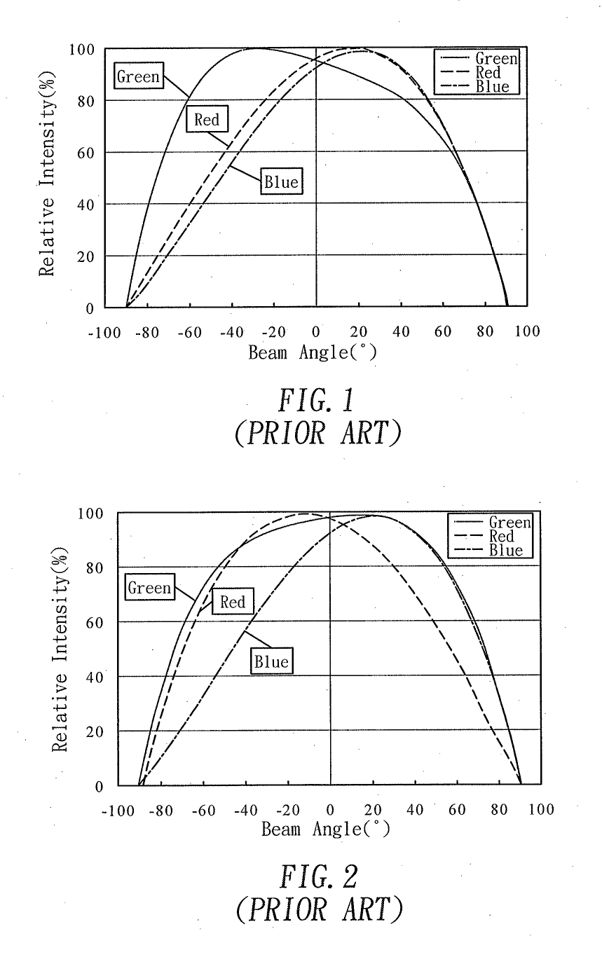

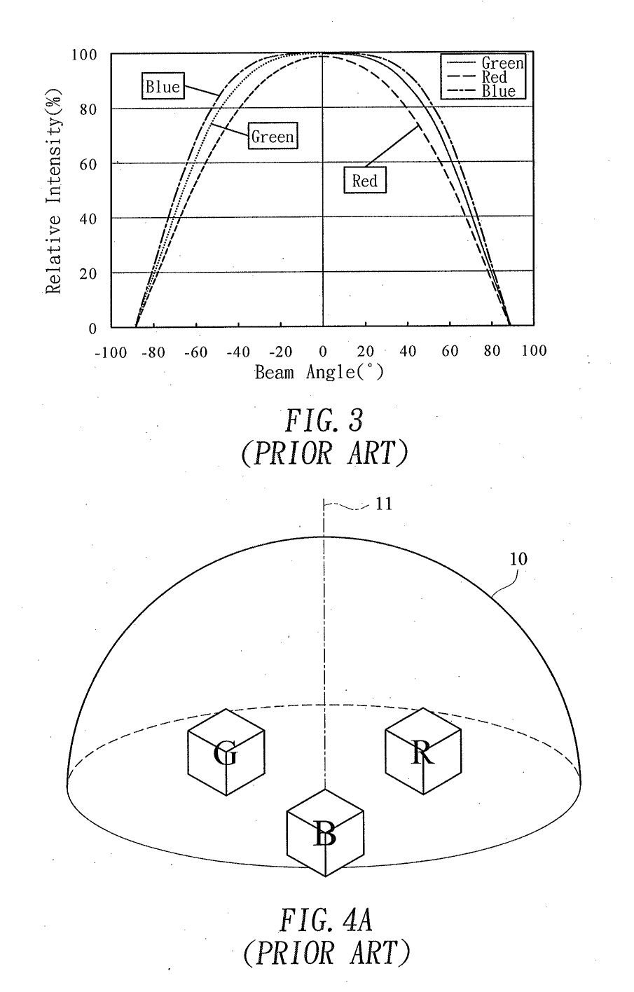

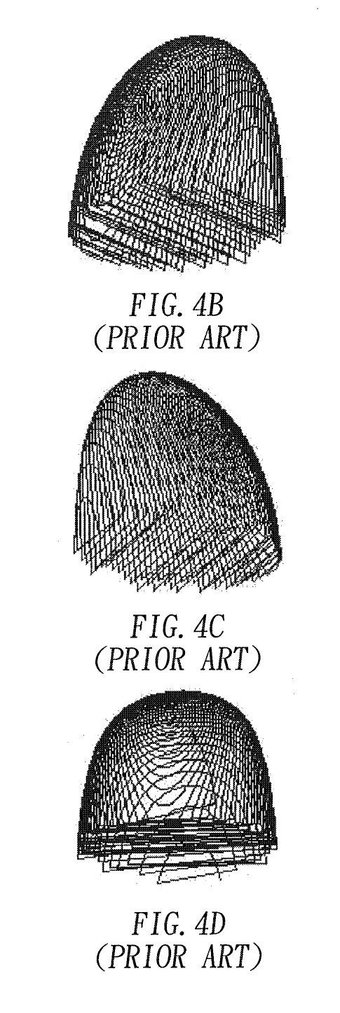

### DETAILED DESCRIPTION OF THE INVENTION

In order to further illustrate the technical means and effects the present invention adopts for achieving the foregoing objectives, with combination of the accompanying drawings and some preferred embodiments, the specific implementing means, manufacturing method, steps, features as well as the effects of the multi-field arranging method of LED chips under a single lens proposed by the present invention will be described in detail below.

The foregoing and other technical contents, features and effects of present invention, will be illustrated in detail below by some preferred embodiments together with the accompanying drawing. Through the detailed description of the invention, people skilled in the art would further and better understand the technical means adopted by the present invention to achieve the specific objectives and the effects of the present invention. However, the accompanying drawings are for the purposes of reference and illustration and shall form no limitation to the present invention.

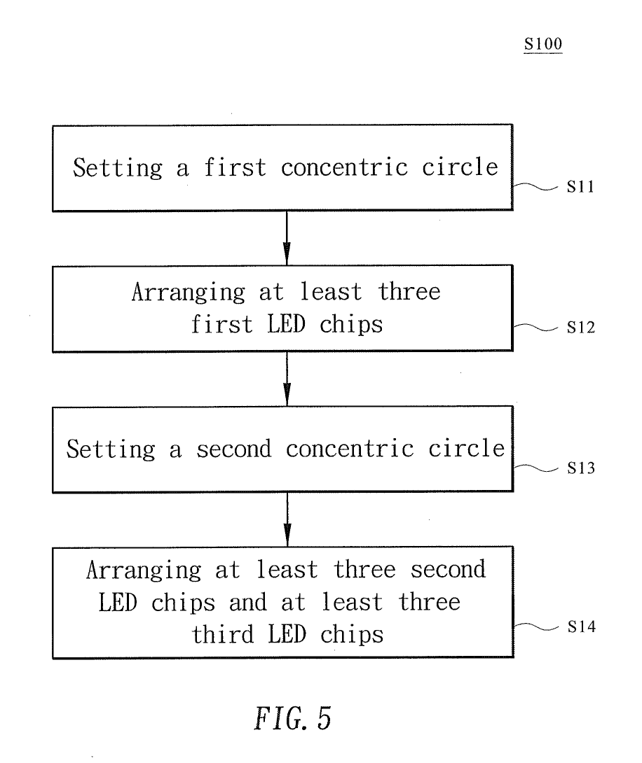

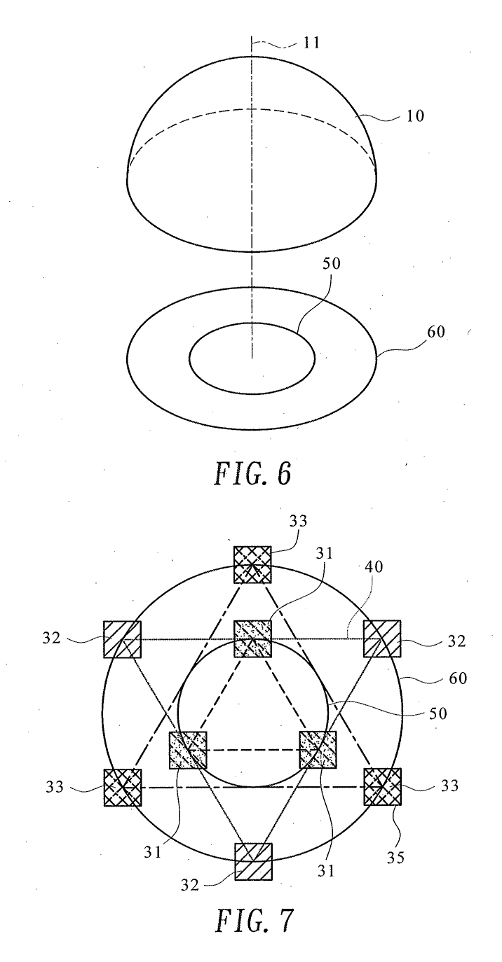

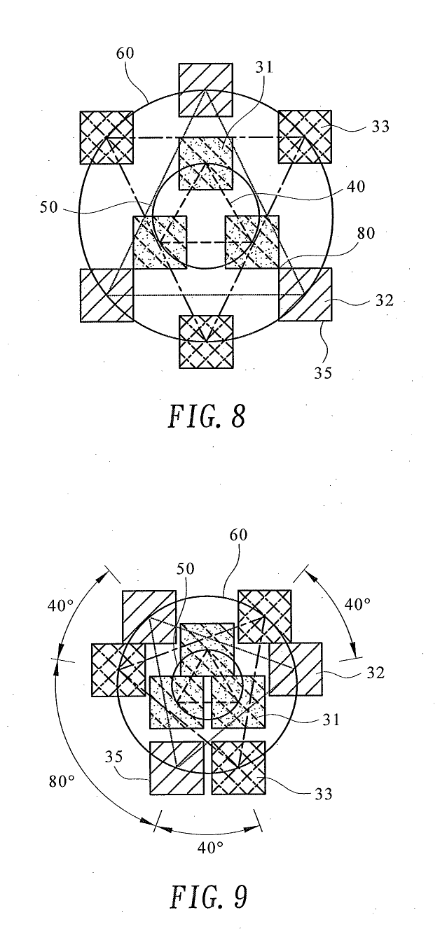

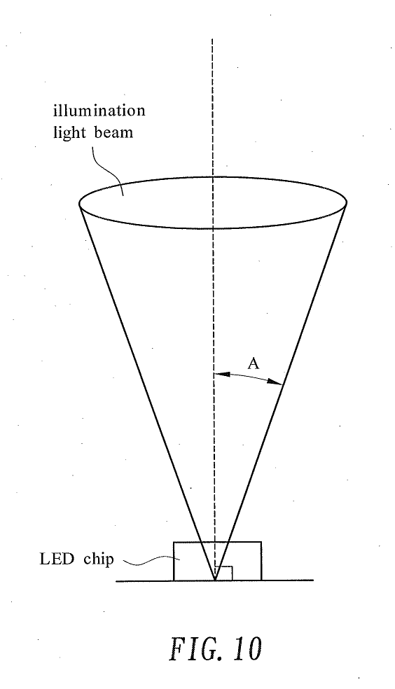

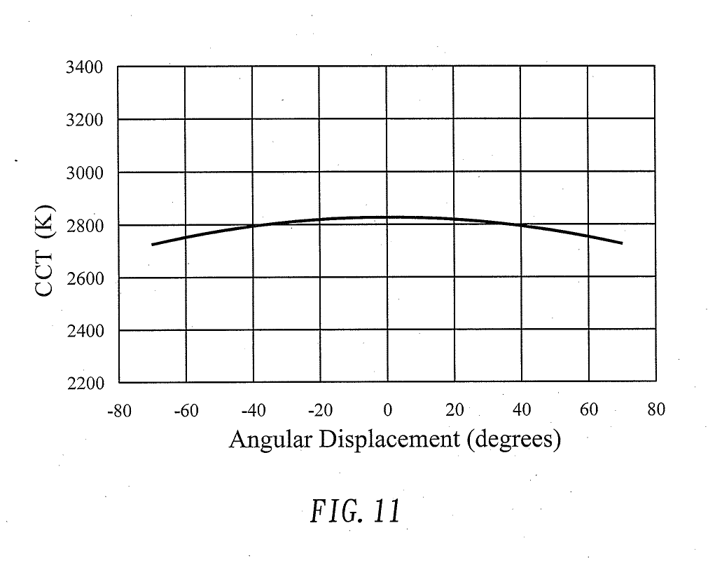

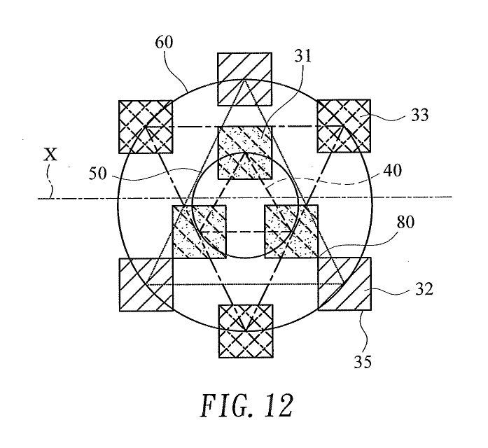

FIG. 5 is a flowchart of a multi-field arranging method of LED chips under a single lens according to a preferred embodiment of the present invention; FIG. 6 is a view of the first and the second concentric circles under the single lens according to FIG. 5; FIG. 7 is an exemplificative arrangement of the LED chips according to the preferred embodiment; FIG. 8 is another exemplificative arrangement of the LED chips according to the preferred embodiment; FIG. 9 is still another exemplificative arrangement of the LED chips according to the preferred embodiment; FIG. 10 is the graphical presentation of a vertical divergence angle of a LED chip; FIG. 11 is the graphical presentation of the evener color temperature distribution of the LED chips in one illuminating direction according to the preferred embodiment of the invention; and FIG. 12 is the graphical presentation of the scanning arrangement for obtaining the color temperature distribution as in FIG. 11.

Referring to FIG. 5, the multi-field arranging method S100 of the present invention comprises the steps of: setting a first concentric circle S11; arranging at least three first LED chips S12; setting a second concentric circle S13; and arranging at least three second LED chips and at least three third LED chips S14.

In the step of setting a first concentric circle S11, referring to FIG. 6, the first concentric circle 50 is formed on a bottom of a hemispherical lens 10 and centered at an axis 11 of the hemispherical lens 10.

In the step of arranging at least three first LED chips S12, referring to FIG. 7 and FIG. 10, the first LED chips 31 of a first vertical divergence angle are equidistantly arranged on the first concentric circle 50. The three first LED chips 31 may be arranged into an equilateral triangle 40. Wherein the vertical divergence angle of a LED chip as denoted by A in FIG. 10 is the angle of the illumination light to beam measured from the normal line of the LED chip.

In the step of setting a second concentric circle S13, referring to FIG. 6 and FIG. 7, the second concentric circle 60 is also formed on the bottom of the hemispherical lens 10, and also centered at the axis 11 of the hemispherical lens 10. The second concentric circle 60 is larger than the first concentric circle 50 in radius. In other words, the second concentric circle 60 is formed to circle the first concentric circle 50.

In the step of arranging at least three second LED chips and at least three third LED chips S14, referring to FIG. 7 and FIG. 10, the second LED chips 32 of a second vertical divergence angle and the third LED chips 33 of a third vertical divergence angle are arranged on the second concentric circle 60 alternately and equidistantly. Wherein the vertical divergence angle of a second LED chip or the vertical divergence angle of a third LED chip is also denoted as the angle A as in FIG. 10, which is the angle of the illumination light beam measured from the normal line of the LED chip.

The second LED chips 32 and the third LED chips 33 on the second concentric circle 60 may contact the first LED chips 31 on the first concentric circle 50, so as to reduce the interval between adjacent LED chips 31, 32, and 33, and thereby downsize the overall configuration. For example, referring to FIG. 8, the second LED chips 32 on the second concentric circle 60 may contact the first LED chips 31 on the first concentric circle 50. Since each of the LED chips 31, 32, and 33 is a square of a same size, when the adjacent first LED chip 31 contact the second LED chip 32, a distance between their centers is \sqrt{2} times the length of one side of one LED chip.

Referring to FIG. 9, the multi-field arranging method S100 allows the arrangement of the maximum density, wherein one of first imaginary lines, which is a link line between the center of the second concentric circle 60 and the center of one second LED chip 32, has an included angle of 40° with one of second imaginary lines, which is a link between the center of the second concentric circle 60 and the center of one of the third LED chips 33 anticlockwise adjacent to said second LED chip 32, while one of the first imaginary lines has an included angle of 80° with one of the third imaginary lines, which is a link between the center of the second concentric circle 60 and the center of one of the third LED chips 33 clockwise adjacent to said second LED chip 32. At this time, the second LED chips 32 and the third LED chips 33 may contact the first LED chips 31, and a distance between any of the second LED chips and the adjacent first LED chip 31, or between any of the third LED chips and the adjacent first LED chip 31 is smaller than \sqrt{2} times the length of one side of one LED chip, thereby achieving the arrangement of the maximum density.

In addition, the first LED chips 31, the second LED chips 32, and the third LED chips 33 may be composed of red LED chips, green LED chips, and blue LED chips. Wherein the vertical divergence angle of a red LED chip is smaller than that of a blue LED chip or a green LED chip.

Since the multi-field arranging method S100 arranges the LED chips equidistantly, when three of the second LED chips 32 and three of the third LED chips 33 are provided on the second concentric circle 60, the chips 31, 32 or 33 may form an equilateral triangle 40. Meantime, each of the first LED chips 31, the second LED chips 32, and the third LED chips 33 has a bottom 35. When respectively arranged on the first concentric circle 50 and the second concentric circle 60, all the LED chips 31, 32, and 33 have their bottoms 35 mutually parallel.

By using the multi-field arranging method S100, the plural LED chips 31, 32, and 33 can be arranged as close as possible, so the overall configuration can be downsized. In addition, since the LED chips 31, 32 or 33 are foamed into the equilateral triangle 40, the first LED chips 31, the second LED chips 32 or the third to LED chips 33 can have their light patterns compensate mutually so that the light pattern of the LED chips 31 or 32 or 33 is symmetrical, thereby improving color mixture at the peripheral portion of the hemispherical lens 10.

As shown in FIG. 11 is a measurement of the color temperature distribution of a LED arrangement example by using the multi-field arrangement method S100. The measurement of FIG. 11 is obtained by scanning along the line X in the illumination area of the arrangement example as in FIG. 12. As can be seen in the resulting graph of FIG. 11, a fairly evener correlated color temperature (CCT) distribution is obtained.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A multi-field arranging method of LED chips under a single lens, the method comprising steps of:
setting a first concentric circle on a bottom of a hemispherical lens, wherein the first concentric circle is centered at an axis of the hemispherical lens;
arranging at least three first LED chips having a first vertical divergence angle on the first concentric circle, wherein the first LED chips are arranged equidistantly;
setting a second concentric circle on the bottom of the hemispherical lens, wherein the second concentric circle is centered at the axis of the hemispherical lens, and the second concentric circle is larger than the first concentric circle in radius; and
arranging at least three second LED chips and at least three third LED chips, wherein each said second LED chip has a second vertical divergence angle and each said third LED chip has a third vertical divergence angle;
wherein the first vertical divergence angle is smaller than the second vertical divergence angle or the third vertical divergence angle, and the second vertical divergence angle does not equal to the third vertical divergence angle.

2. The multi-field arranging method of claim 1, wherein the first LED chips are arranged into an equilateral triangle.

3. The multi-field arranging method of claim 1, wherein each of the first LED chips, the second LED chips, and the third LED chips has a bottom, and all of the bottoms are mutually parallel.

4. The multi-field arranging method of claim 1, wherein one of first imaginary lines, which is links between a center of the second concentric circle and a center of one said second LED chip, has an included angle of 40° with one of second imaginary lines, which links between the center of the second concentric circle and a center of one said third LED chip anticlockwise adjacent to said second LED chip, while one of the first imaginary lines has an included angle of 80° with one of third imaginary lines, which links between the center of the second concentric circle and the center of one said third LED chip clockwise adjacent to said second LED chip.
